(19) United States
(12) Patent Application Publication
(10) Pub. No.: US 2010/0104860 A1
(43) Pub. Date: Apr. 29, 2010

(54) Cemented Tungsten Carbide-Based Material and Method for Making the Same

(75) Inventors: Chau-Chang Chou, Taichung City (TW); Jyh-Wei Lee, Taipei City (TW); Yen-Yi Chen, Keelung City (TW); Hsin-Han Lin, Rende Shiang (TW)

Correspondence Address: THE WEBB LAW FIRM, P.C., 700 KOPPERS BUILDING, 436 SEVENTH AVENUE, PITTSBURGH, PA, 15219, US

(73) Assignee: NATIONAL TAIWAN OCEAN UNIVERSITY, Keelung (TW)

(21) Appl. No.: 12/430,449

(22) Filed: Apr. 27, 2009

(30) Foreign Application Priority Data
Oct. 23, 2008 (TW) 097140652

(51) Int. Cl. B32B 9/04; B05D 1/36; C23C 16/44

(52) U.S. Cl. 428/332; 428/698; 428/697; 427/419.7; 427/249.13; 427/249.18

(57) ABSTRACT

A cemented tungsten carbide-based material includes: a cemented tungsten carbide substrate having a chromized layer that contains a tungsten carbide and a chromium carbide; and a diamond film formed on said chromized layer. A method for making the cemented tungsten carbide-based material involves subjecting a cemented tungsten carbide substrate to chromization so as to form the cemented tungsten carbide substrate with a chromized layer that contains a tungsten carbide and a chromium carbide; and forming a diamond film on the chromized layer.

### CROSS-REFERENCE TO RELATED APPLICATION

This application claims priority of Taiwanese Application No. 097140652, filed on Oct. 23, 2008.

### BACKGROUND OF THE INVENTION

1. Field of the Invention

The invention relates to a cemented tungsten carbide-based (WC-based) material and a method for making the same, more particularly to a cemented tungsten carbide-based material having a tungsten carbide substrate with a chromized layer that contains a tungsten carbide and a chromium carbide, and a method involving chromizing a cemented tungsten carbide substrate.

2. Description of the Related Art

Cemented tungsten carbide is normally prepared by sintering a WC-based composition containing WC particles and a binder of cobalt (Co). The cemented WC thus formed has excellent wear resistance and hardness, and can be used for high-speed cutting or drilling tools or for molding dies. When the cemented WC is to be used for cutting tools for cutting ceramic materials, or for molding dies for molding optical lenses, a diamond film is normally required to be coated on the cemented WC so as to enhance the hardness, wear resistance, and machinability of the cutting tools, or release efficiency of the molding dies.

It is known in the art that a coated diamond film having a higher ratio of sp³ bonds to sp² bonds possesses a higher mechanical strength. It is also known in the art that the presence of the transitional elements, such as iron (Fe), Co, and Nickel (Ni), on a surface of the WC substrate during deposition of a diamond film on the surface of the WC substrate can cause formation of sp² bonds in the diamond film, which, in turn, results in undesired local graphitization of the diamond film. Since the coating of a diamond film on a cemented WC substrate through chemical vapor deposition techniques is required to be operated at a relatively high temperature, undesired upward diffusion of Co atoms from the cemented WC substrate into the diamond film is likely to occur, which results in local graphitization of the coated diamond film, which, in turn, results in a decrease in the machinability for the coated diamond film.

In order to eliminate the graphitization, it has been proposed that the cemented WC substrate be subjected to an acid-etching treatment so as to remove the Co atoms on a surface of the WC substrate on which the diamond film is to be coated, or be coated with a diffuse-barrier layer thereon to inhibit the diffusion of the Co atoms into the diamond film. The acid-etching treatment is accomplished by immersing the cemented WC substrate into an acid etchant of HNO₃ and H₂O (1:1) for 10 minutes. The acid-etching treatment can improve the quality of the diamond film. However, since the surface of the WC substrate tends to be damaged by the acid etchant, the resistance to deformation resulting from an external stress is significantly decreased, thereby resulting in a decrease in the adhesion of the diamond film to the WC substrate. Moreover, the effect of the acid-etching treatment in inhibiting the diffusion of Co atoms into the diamond film is limited.

Another proposal for solving the problem of the diffusion of Co atoms is to coat a chromium layer as the diffuse-barrier layer on an acid-etching treated cemented WC substrate through physical vapor deposition (PVD) techniques prior to formation of the diamond film on the cemented WC substrate. The coated Cr layer normally has a layer thickness of 0.6 μm. Referring to FIG. 1, a scanning electron microscope (SEM) image of a diamond film on a chromium layer of a cemented WC substrate shows that the diamond film contains solely diamond grains, which is an indication that the diamond film thus formed has an excellent quality. Hence, the Cr layer coated on the WC substrate can prevent graphitization from occurring and improve the quality of the diamond film. However, as illustrated in FIG. 2, which shows an adhesion test result conducted under a load of 150 kgf for 30 seconds using an indenter with a radius of 0.2 mm according to a standard of Part 4 of VDI 3824 (The Daimler-Bens Rockwell-C adhesion test, HRC-DB adhesion test), the Rockwell adhesion of the diamond film thus formed is rated HF6, which is the worst level, i.e., the poorest adhesion strength. Note that the level of the Rockwell adhesion is rated from HF1 to HF6 which correspond respectively to six different images of adhesion strength quality. The lower the level of the Rockwell adhesion, the higher will be the adhesion strength. The test result also shows that the diamond film peeled from the Cr layer on the cemented WC substrate under the aforesaid test conditions.

### SUMMARY OF THE INVENTION

Therefore, the object of the present invention is to provide a cemented tungsten carbide-based material that can overcome the aforesaid drawbacks associated with the prior art.

Another object of the present invention is to provide a method for making the cemented tungsten carbide-based material.

According to one aspect of this invention, there is provided a cemented tungsten carbide-based material that comprises: a cemented tungsten carbide substrate having a chromized layer that contains a tungsten carbide and a chromium carbide; and a diamond film formed on the chromized layer.

According to another aspect of this invention, there is provided a method for making a cemented tungsten carbide-based material. The method comprises: subjecting a cemented tungsten carbide substrate to chromization so as to form the cemented tungsten carbide substrate with a chromized layer that contains a tungsten carbide and a chromium carbide; and forming a diamond film on the chromized layer.

### BRIEF DESCRIPTION OF THE DRAWING

Other features and advantages of the present invention will become apparent in the following detailed description of the preferred embodiments of this invention, with reference to the accompanying drawings, in which:

FIG. 1 is a SEM image to illustrate surface morphology of a diamond film formed on a chromium layer in a conventional manner;

FIG. 2 is a SEM image to illustrate the adhesion test result of the diamond film of FIG. 1;

FIG. 3 is a fragmentary schematic view to illustrate a layer structure of the preferred embodiment of a cemented tungsten carbide-based material according to this invention;

FIG. 4 is a X-Ray Diffraction (XRD) plot to illustrate the crystalline structure of a chromized layer formed by conducting pack chromization for 1 hour;

FIG. 5 is a X-Ray Diffraction (XRD) plot to illustrate the crystalline structure of a chromized layer of Example 1 (E1) according to this invention;

FIG. 6 is a SEM image to illustrate the surface morphology of a diamond film of Example 1 (E1);

FIGS. 7a and 7b are SEM and back scattering electron (BSE) images, respectively, to illustrate the adhesion test result of the diamond film of Example 1 (E1);

FIG. 8 is a XRD plot to illustrate the crystalline structure of the diamond film of Example 1 (E1);

FIG. 9 is a Raman spectrum to illustrate sp³ bonding and sp² bonding of the diamond film of Example 1 (E1);

FIG. 10 is a SEM image to illustrate the adhesion test result of a chromized layer of Example 2 (E2) according to this invention;

FIG. 11 is a SEM image to illustrate the adhesion test result of a diamond film of Example 2 (E2);

FIG. 12 is a Raman spectrum to illustrate sp³ bonding and sp² bonding of the diamond film of Example 2 (E2);

FIG. 13 is a SEM image to illustrate the adhesion test result of a chromized layer of Example 3 (E3) according to this invention;

FIG. 14 is a SEM image to illustrate the adhesion test result of a diamond film of Example 3 (E3);

FIG. 15 is a Raman spectrum to illustrate sp³ bonding and sp² bonding of the diamond film of Example 3 (E3);

FIG. 16 is a SEM image to illustrate the adhesion test result of a chromized layer of Example 4 (E4) according to this invention;

FIG. 17 is a XRD plot to illustrate the crystalline structure of a diamond film of Example 4 (E4); and

FIG. 18 is a Raman spectrum to illustrate sp³ bonding and sp² bonding of the diamond film of Example 4 (E4).

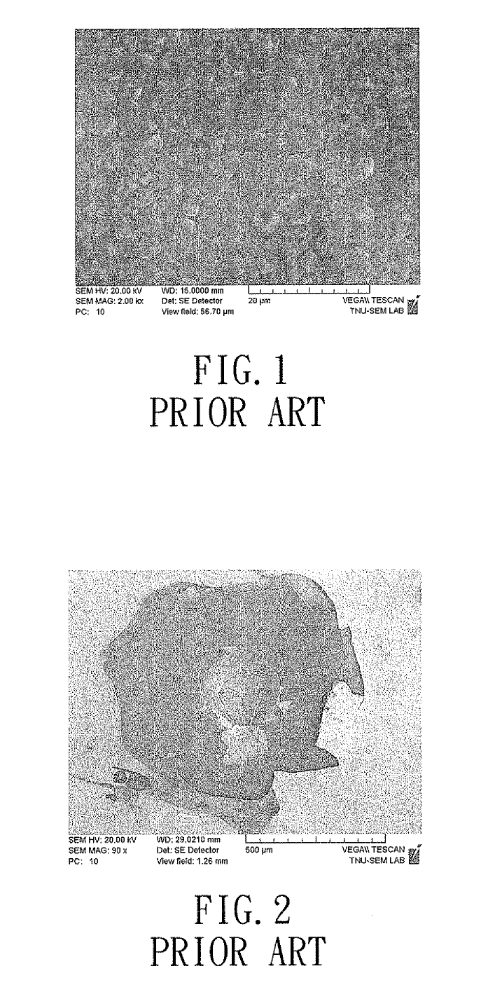

### DETAILED DESCRIPTION OF THE PREFERRED EMBODIMENTS

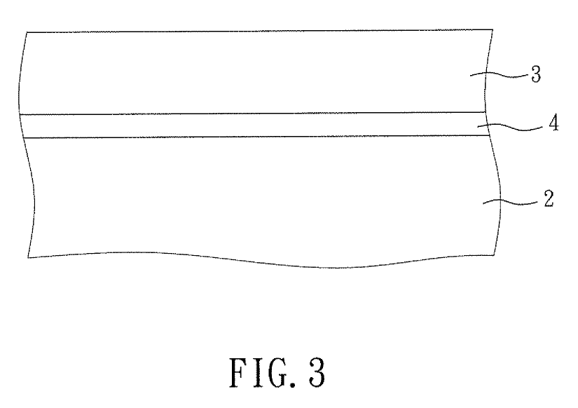

FIG. 3 illustrates the preferred embodiment of a cemented tungsten carbide-based material according to this invention. The cemented tungsten carbide-based material includes: a cemented tungsten carbide substrate 2 having a chromized layer 4 that contains a tungsten carbide (WC) and a chromium carbide; and a diamond film 3 formed on the chromized layer 4.

Preferably, the cemented tungsten carbide substrate 2 contains cobalt (Co) in an amount ranging from about 6 wt % to about 12 wt %, and WC in an amount ranging from about 88 wt % to about 94 wt %.

Preferably, the chromized layer 4 further contains a chromium iron carbide. The chromium carbide is crystalline, and is selected from the group consisting of Cr₂₃C₆, Cr₇C₃, and a combination thereof. The chromium iron carbide is crystalline, and is selected from the group consisting of (CrFe)₂₃C₆, (CrFe)₇C₃, and a combination thereof. Preferably, the chromized layer 4 further contains a chromium nitride, e.g., (CrFe)₂N₁₋ₓ.

The chromized layer 4 has a layer thickness preferably ranging from 3.0 μm to 8.0 μm, more preferably, ranging from 4.5 μm to 7.6 μm.

The preferred embodiment of a method for making the cemented tungsten carbide-based material according to this invention includes: subjecting the cemented tungsten carbide substrate 2 to pack chromization using a chromization powder under an elevated temperature sufficient to cause diffusion of Cr atoms of the chromization powder into the cemented tungsten carbide substrate 2 to react with carbon atoms of the cemented tungsten carbide substrate 2 so as to form the cemented tungsten carbide substrate with the chromized layer 4; and subsequently forming the diamond film 3 on the chromized layer 4.

Preferably, the pack chromization is conducted at a temperature ranging from 800° C. to 950° C. for a treatment time ranging from 2 hours to 9 hours. More preferably, the temperature ranges from 850° C. to 950° C., and the treatment time ranges from 2 hours to 6 hours. Most preferably, the treatment time ranges from 2.25 hours to 4 hours.

Alternatively, formation of the chromized layer 4 may possibly be conducted through salt-bath chromizing or fluidized-bed chromizing techniques.

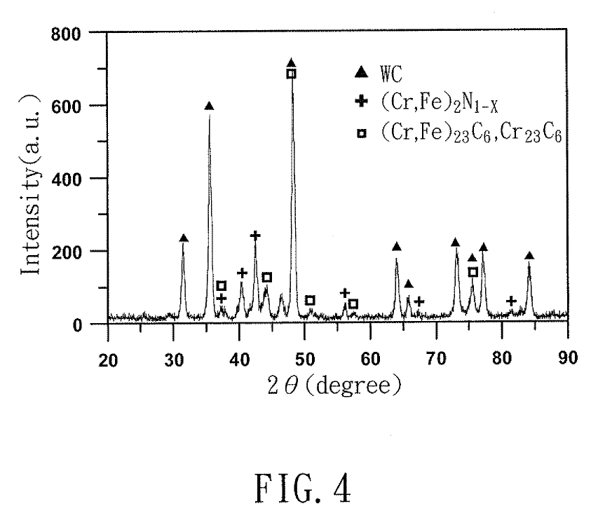

FIG. 4 is a XRD plot to illustrate a crystalline structure of a chromized layer formed through pack chromization techniques under an elevated temperature of 850° C. for 1 hour. From the XRD plot shown in FIG. 4, the chromized layer is crystalline, and contains WC (according to No. 51-0939 of JCPDF card), (CrFe)₂N₁₋ₓ (according to No. 19-0330 of JCPDF card), Cr₂₃C₆, and (CrFe)₂₃C₆ (according to No. 35-0783 of JCPDF card), which suggests that the Cr atoms from the chromization powder are diffused into the WC substrate during pack chromization to react with the C atoms of the tungsten carbide so as to form the chromium carbide and the chromium iron carbide.

Preferably, the diamond film 3 is formed through chemical vapor deposition (CVD) techniques under a substrate-temperature ranging from 600° C. to 690° C. More preferably, the substrate-temperature ranges from630° C. to 680° C. It is noted that the substrate-temperature is measured using a thermocouple (not shown) that is in contact with a bottom surface of the cemented tungsten carbide substrate 2.

Preferably, the method of the preferred embodiment further includes subjecting the chromized cemented tungsten carbide substrate 2 to an air-cooling treatment prior to formation of the diamond film 3 thereon for releasing residual stress in the chromized cemented tungsten carbide substrate 2.

It is noted that different mechanical properties of the cemented tungsten carbide can be achieved through addition of a small amount of TiC particles or TaC particles in the cemented tungsten carbide.

The merits of the cemented tungsten carbide-based material will become apparent with reference to the following Examples.

### EXAMPLES

### Example 1 (E1)

The cemented tungsten carbide-based material of Example 1 (E1) was prepared by the following steps.

A cemented WC substrate consisting of 94 wt % WC and 6 wt % Co and having a size of 15 mm×15 mm×1 mm was cleaned with water for 10 minutes and subsequently with acetone for 10 minutes by ultrasonic cleaning. The cemented WC substrate thus cleaned was dried. The cemented WC substrate was then put into a container containing a chromization powder including: a Fe—Cr powder (30 wt %) having Cr (71 wt %), C (0.03 wt %), and Fe (28.97 wt %); NH₄Cl (2.5 wt %); and an Al₂O₃ powder (67.5 wt %). The cemented WC substrate was subjected to pack chromization for a treatment time of 4 hours by placing the container in a chromizing furnace that was introduced with an Ar gas and operated at an elevated temperature of 950° C. so as to form the cemented WC substrate with a chromized layer having a layer thickness of 7.51 μm. Then, the chromized cemented WC substrate was subjected to an air-cooling treatment for releasing residual stress in the chromized cemented WC substrate resulting from the elevated temperature. The chromized cemented WC substrate was subsequently immersed in a suspension containing acetone and a diamond powder with a particle size distribution of 4 nm to 12 nm so as to form crystalline seeds on the chromized layer. Finally, the chromized cemented WC substrate was deposited a diamond film thereon by placing the chromized cemented WC substrate in a hot filament CVD (HFCVD) system operated at a filament temperature of 1900° C. (i.e., a substrate-temperature of 650° C.), a working pressure of 50 Torr, a volume flow rate of 255 sccm of a gaseous mixture of CH₄ and H₂ (CH₄:H₂=5 sccm:250 sccm), a depositing time of 5 hours, and a working distance (i.e., a distance between the filament and the chromized cemented WC substrate) of 6 mm.

The amounts of Cr and Co of the chromized layer of the cemented WC substrate were determined through energy dispersive spectrometry (EDS) mapping (not shown). No Co atom was found in the chromized layer through the analysis of EDS mapping. A SEM cross-sectional image (not shown) of the chromized layer shows that it has the layer thickness of 7.51 μm.

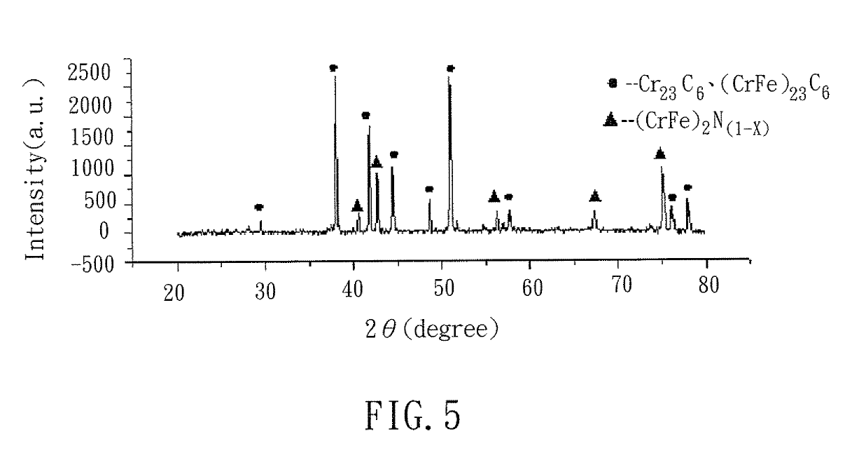

The XRD plot shown in FIG. 5 was obtained through grazing incident diffraction techniques. From the XRD plot shown in FIG. 5, the chromized layer of Example 1 (E1) is crystalline, and contains (CrFe)₂N₁₋ₓ (according to No. 19-0330 of JCPDF card), Cr₂₃C₆, and (CrFe)₂₃C₆ (according to No. 35-0783 of JCPDF card). It is noted that, in FIG. 5, since only a relatively shallow depth of the chromized layer was detected by the grazing incident diffraction, the content of the WC in this detected region of the chromized layer is very rare, and can not be detected.

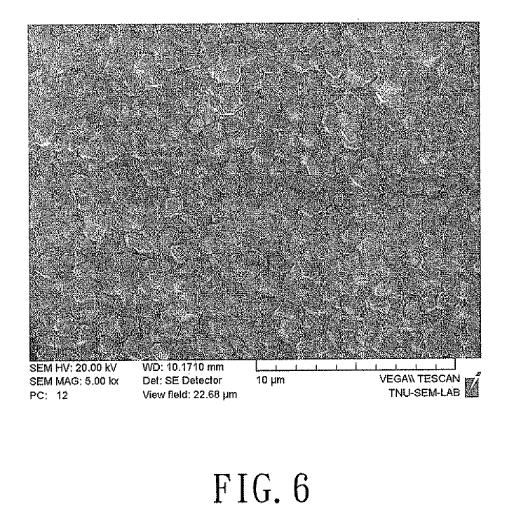

The SEM image shown in FIG. 6 demonstrates that the diamond film of Example 1 (E1) contains solely diamond grains, which is an indication that the diamond film thus formed has an excellent quality.

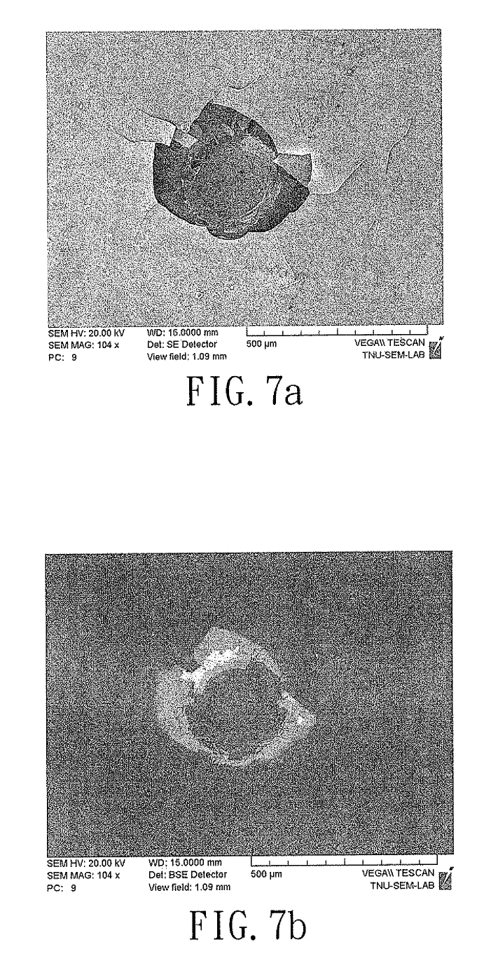

From the SEM and BSE images shown in FIGS. 7a and 7b, the Rockwell adhesion of the diamond film of Example 1 (E1) (see Table 1) has a level of HF4 according to Part 4 of VDI 3824 (HRC-DB adhesion test).

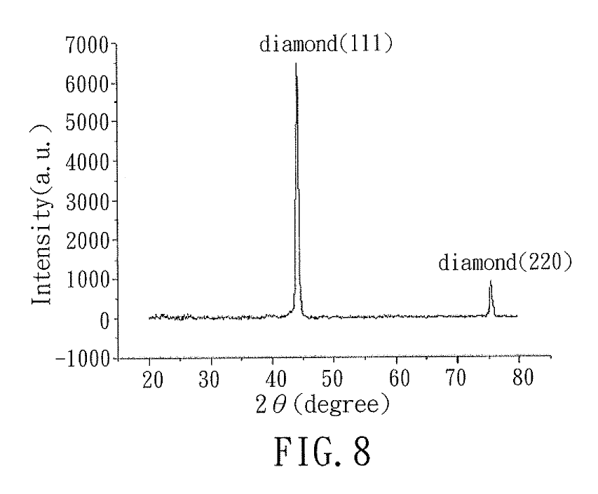

From the XRD plot shown in FIG. 8, the diamond film of Example 1 (E1) has diffractive peaks of (111) and (220). The result shown in FIG. 8 demonstrates that the diamond film of Example 1 (E1) has a good crystallinity and a crystalline structure of diamond cubic (DC).

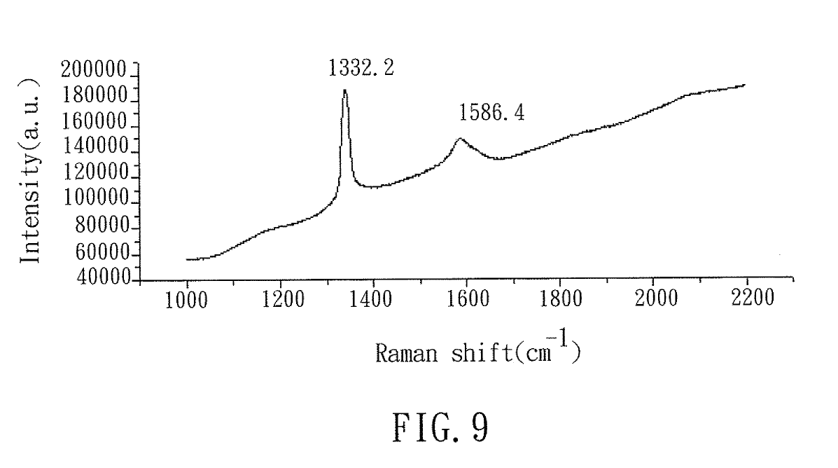

The Raman spectrum shown in FIG. 9 illustrates sp³ bonding and sp² bonding of the diamond film of Example 1 (E1). A weak peak of graphite (sp²) located at 1586.4 cm⁻¹ and a strong peak of diamond (sp³) located at 1332.2 cm⁻¹ are found in FIG. 9, which demonstrates that the diamond film has a lower percentage of sp² bonding and a higher percentage of sp³ bonding.

The results shown in FIGS. 8 and 9 demonstrate that the diamond film of Example 1 (E1) has an excellent quality.

### Example 2 (E2)

The cemented tungsten carbide-based material of Example 2 (E2) was prepared by steps and operation conditions similar to those of Example 1 (E1), except that the cemented WC substrate consists of 88 wt % WC and 12 wt % Co, and that the elevated temperature of the chromizing operation was 850° C.

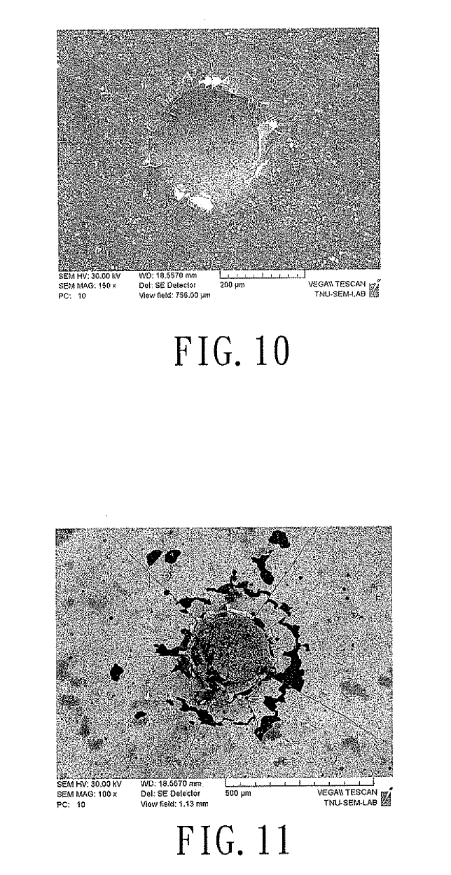

FIGS. 10 and 11 show that the Rockwell adhesions of the chromized layer and the diamond film of Example 2 (E2) have levels of HF3 and HF4 (see Table 1), respectively.

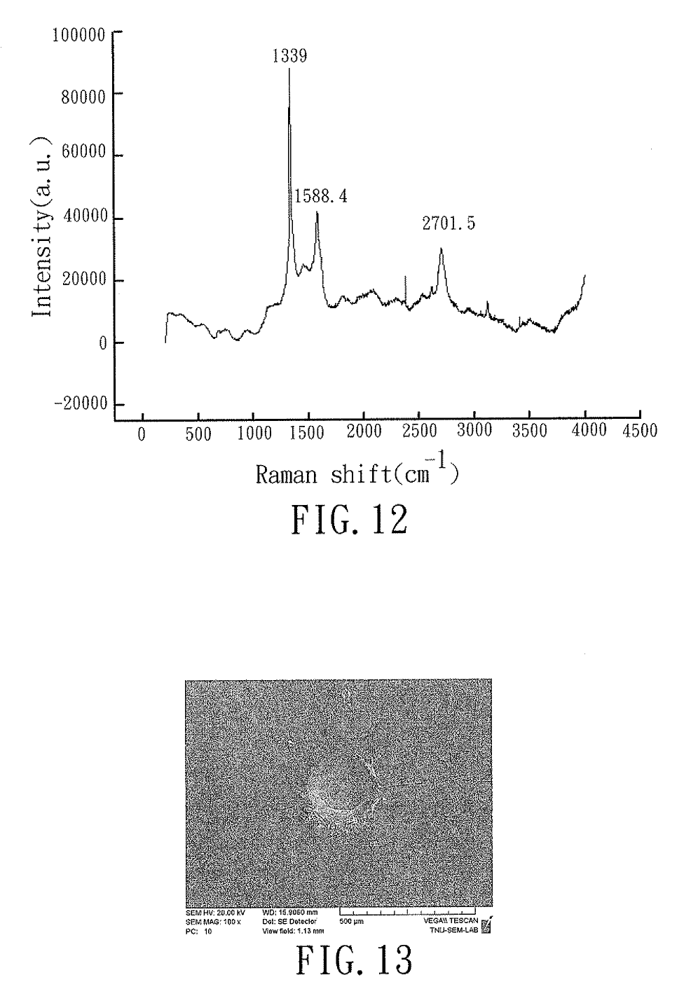

The Raman spectrum shown in FIG. 12 illustrates sp³ bonding and sp² bonding of the diamond film of Example 2 (E2). Two weak peaks of graphite (sp² ) located at 1588.4 cm⁻¹ and 2719.2 cm⁻¹, respectively, and a strong peak of diamond (sp³) located at 1339 cm⁻¹ are found in FIG. 12, which demonstrates that the diamond film has a lower percentage of sp² bonding and a higher percentage of sp³ bonding.

### Example 3 (E3)

The cemented tungsten carbide-based material of Example 3 (E3) was prepared by steps and operation conditions similar to those of Example 2 (E2), except that the treatment time of the chromizing operation was 2.25 hours.

FIGS. 13 and 14 show that the Rockwell adhesions of the chromized layer and the diamond film of Example 3 have levels of HF2 and HF4 (see Table 1), respectively.

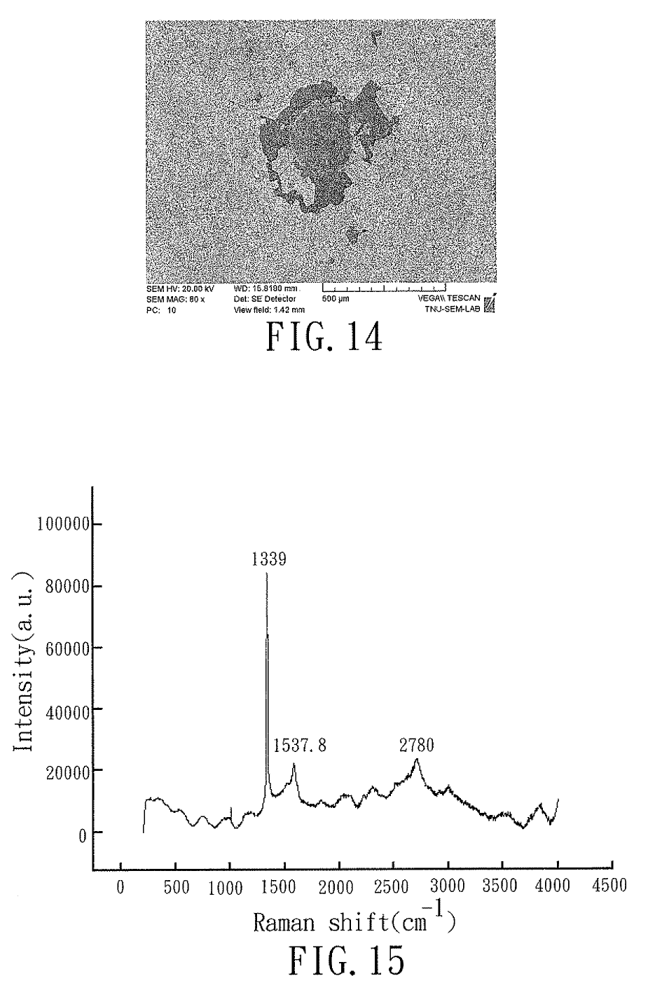

The Raman spectrum shown in FIG. 15 illustrates sp³ bonding and sp² bonding of the diamond film of Example 3 (E3). Two weak peaks of graphite (sp²) located at 1537.8 cm⁻¹ and 2780 cm⁻¹, respectively, and a strong peak of diamond (sp³) located at 1339 cm⁻¹ are found in FIG. 15, which demonstrates that the diamond film has a lower percentage of sp² bonding and a higher percentage of sp³ bonding.

### Example 4 (E4)

The cemented tungsten carbide-based material of Example 4 (E4) was prepared by steps and operation conditions similar to those of Example 1 (E1), except that the treatment time and the elevated temperature of the chromizing operation were 2.25 hours and 850° C., respectively.

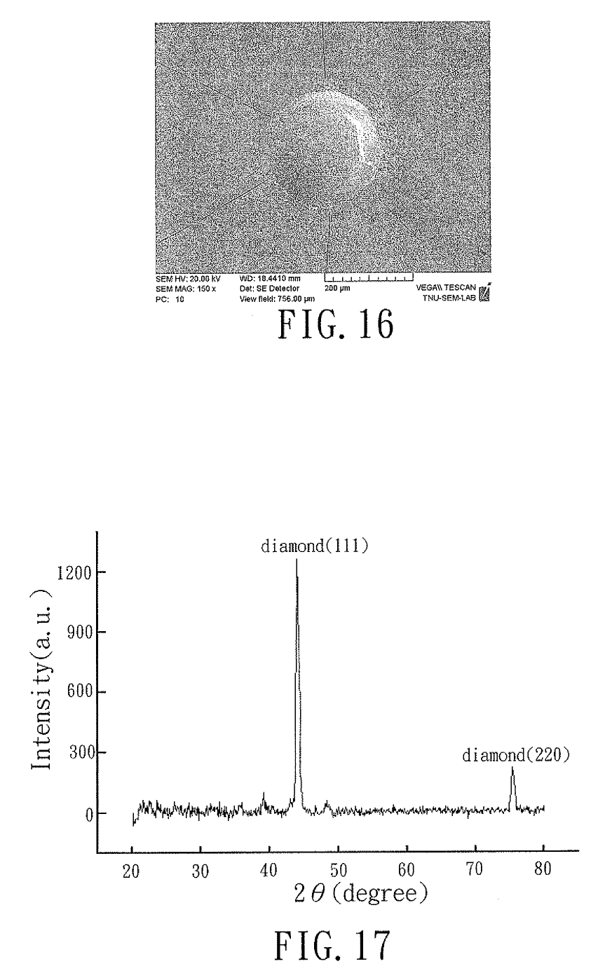

FIG. 16 shows that the Rockwell adhesion of the chromized layer has a level of HF2 (see Table 1).

From the XRD plot shown in FIG. 17, the diamond film of Example 4 (E4) has diffractive peaks of (111) and (220). The result shown in FIG. 17 demonstrates that the diamond film of Example 4 (E4) has a good crystallinity and a crystalline structure of DC.

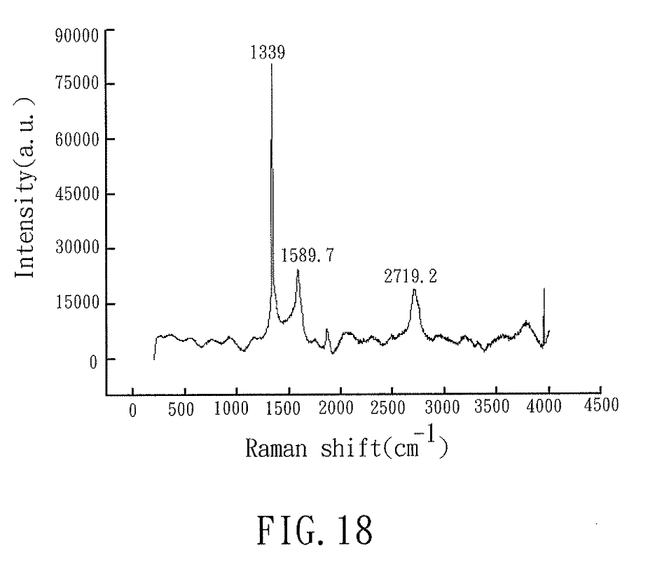

The Raman spectrum shown in FIG. 18 illustrates sp³ bonding and sp² bonding of the diamond film of Example 4 (E4). Two weak peaks of graphite (sp²) located at 1589.7 cm⁻¹ and 2719.2 cm⁻¹, respectively, and a strong peak of diamond (sp³) located at 1339 cm⁻¹ are found in FIG. 18, which demonstrates that the diamond film has a lower percentage of sp² bonding and a higher percentage of sp³ bonding.

### Example 5 (E5)

The cemented tungsten carbide-based material of Example 5 (E5) was prepared by steps and operation conditions similar to those of Example 1 (E1), except that the treatment time of the chromizing operation was 9 hours. The chromized layer thus obtained has a layer thickness of 11.27 μm, and a level of HF6 for the Rockwell adhesion (see Table 1).

TABLE 1

| | Chromized layer | | | | Diamond film | | |
|---|---|---|---|---|---|---|---|
| | Temp. | Time | Thickness | Adhe- | Temp. | | Adhe- |
| | (° C.) | (hr) | (μm) | sion | (° C.) | Property | sion |
| E1 | 950 | 4 | 7.51 | — | 650 | Diamond | HF4 |
| E2 | 850 | 4 | — | HF3 | 650 | Diamond | HF4 |
| E3 | 850 | 2.25 | — | HF2 | 650 | Diamond | HF4 |
| E4 | 850 | 2.25 | — | HF2 | 650 | Diamond | — |
| E5 | 950 | 9 | 11.27 | — | 650 | Diamond | HF6 |

—: measurement not taken

In conclusion, by chromizing the cemented tungsten carbide substrate so as to form the chromized layer on the cemented tungsten carbide substrate according to the method of this invention, the diamond film deposited on the chromized layer can have a relatively high adhesion and an excellent quality as a result of eliminating diffusion of Co atoms into the diamond film.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A cemented tungsten carbide-based material comprising:
a cemented tungsten carbide substrate having a chromized layer that contains a tungsten carbide and a chromium carbide; and
a diamond film formed on said chromized layer.

2. The cemented tungsten carbide-based material of claim 1, wherein said chromized layer further contains a chromium iron carbide, said chromium carbide being crystalline and being selected from the group consisting of Cr₂₃C₆, Cr₇C₃, and a combination thereof, said chromium iron carbide being crystalline and being selected from the group consisting of (CrFe)₂₃C₆, (CrFe)₇C₃, and a combination thereof.

3. The cemented tungsten carbide-based material of claim 2, wherein said chromized layer has a layer thickness ranging from 3.0 μm to 8.0 μm.

4. The cemented tungsten carbide-based material of claim 3, wherein said layer thickness of said chromized layer ranges from 4.5 μm to 7.6 μm.

5. The cemented tungsten carbide-based material of claim 1, wherein said chromized layer is formed by chromizing said cemented tungsten carbide substrate through pack chromization techniques under an elevated temperature ranging from 800° C. to 950° C. for a treatment time ranging from 2 hours to 9 hours.

6. The cemented tungsten carbide-based material of claim 5, wherein said elevated temperature ranges from 850° C. to 950° C., and said treatment time ranges from 2 hours to 6 hours.

7. The cemented tungsten carbide-based material of claim 5, wherein said diamond film is formed through chemical vapor deposition techniques under a substrate-temperature ranging from 600° C. to 690° C.

8. The cemented tungsten carbide-based material of claim 7, wherein said substrate-temperature ranges from 630° C. to 680° C.

9. A method for making a cemented tungsten carbide-based material, comprising:
subjecting a cemented tungsten carbide substrate to chromization so as to form the cemented tungsten carbide substrate with a chromized layer that contains a tungsten carbide and a chromium carbide; and
forming a diamond film on the chromized layer.

10. The method of claim 9, wherein the chromized layer further contains a chromium iron carbide, the chromium carbide being crystalline and being selected from the group consisting of Cr₂₃C₆, Cr₇C₃, and a combination thereof, the chromium iron carbide being crystalline and being selected from the group consisting of (CrFe)₂₃C₆, (CrFe)₇C₃, and a combination thereof.

11. The method of claim 9, wherein formation of the chromized layer is conducted through pack chromization techniques under an elevated temperature ranging from 800° C. to 950° C. for a treatment time ranging from 2 hours to 9 hours.

12. The method of claim 11, wherein the elevated temperature ranges from 850° C. to 950° C., and the treatment time ranges from 2 hours to 6 hours.

13. The method of claim 9, wherein formation of the diamond film is conducted through chemical vapor deposition techniques under a substrate-temperature ranging from 600° C. to 690° C.

14. The method of claim 13, wherein the substrate-temperature ranges from 630° C. to 680° C.

15. The method of claim 13, further comprising subjecting the chromized cemented tungsten carbide substrate to an air-cooling treatment prior to formation of the diamond film thereon for releasing residual stress in the chromized cemented tungsten carbide substrate.
